(19) United States
(12) Patent Application Publication
(10) Pub. No.: US 2009/0233058 A1
(43) Pub. Date: Sep. 17, 2009

(54) Carbon nanotube structure and method for producing the same

(76) Inventors: Kenji Hata, Ibaraki (JP); Yuuhei Hayamizu, Ibaraki (JP); Takeo Yamada, Ibaraki (JP)

Correspondence Address: WENDEROTH, LIND & PONACK, L.L.P., 1030 15th Street, N.W.,, Suite 400 East, Washington, DC, 20005-1503, US

(21) Appl. No.: 12/379,801

(22) Filed: Mar. 2, 2009

(30) Foreign Application Priority Data
Feb. 29, 2008 (JP) 2008-051320

(51) Int. Cl. B32B 5/16; C23C 16/44

(52) U.S. Cl. 428/195.1; 427/255.28

(57) ABSTRACT

An arbitrary three-dimensional shaped structure which is integrally formed with only carbon nanotubes having desired physical properties and electrical properties, and anisotropy, and a method for producing the same are disclosed. The carbon nanotube structure is constituted of a carbon nanotube aggregate comprising plural carbon nanotubes oriented in the same direction, wherein the carbon nanotube has weight density of 0.1 g/cm³ or more, the structure comprises a first part contacting a base, a second part separated from the base, and a curved third part which connects the first part and the second part, and orientation axes of at least a part of carbon nanotubes in the first part, the second part and the third part are continued.

### TECHNICAL FIELD

The present invention a carbon nanotube structure and a method for producing the same. More particularly, the invention relates to a carbon nanotube structure having a three-dimensional shaped part constituted of carbon nanotube aggregate comprising plural carbon nanotubes oriented in one direction and a method for producing the same.

### BACKGROUND ART

In recent years, momentum to apply carbon nanotubes (hereinafter referred to as “CNT”) having peculiar physical and chemical properties to a device for micromachine (MEMS) and an electronic device is enhanced. For example, the technology of adhering rear anchor of a probe comprising CNT to a pyramid part of a cantilever by a separate step to constitute a probe of an atomic force microscope is known as described in, for example, JP-A-2005-319581. However, in this technology, a cantilever and a probe are separate members formed individually, and production steps are liable to be complicated.

Furthermore, the technology of obtaining a nanometer size structure or an MEMS structure by forming a mold pattern on a substrate by patterning technique, packing a solution obtained by dispersing CNT in a solvent in the mold pattern and volatilizing the solvent is known as described in, for example, JP-A-2007-63116. However, in this technology, the production steps are complicated and additionally it is difficult to control orientation of CNT. In other words, it is known that CNT aggregate comprising plural CNTs oriented in the same direction has different properties (anisotropy) between an orientation direction and a direction perpendicular thereto in physical properties such as electric properties (for example, conductivity), optical properties (for example, transmittance) and mechanical properties (for example, flexural properties). However, it is difficult for the technology described in JP-A-2007-63116 to impart anisotropy to the completed structure in terms of its production method. Thus, when the orientation of plural CNTs is random, plural CNTs cannot uniformly be packed without space. Therefore, it is difficult to obtain high density CNT aggregate having the desired mechanical strength.

A device is known wherein concave portions or convex portions are formed on a substrate, and plural CNTs formed by vertically orienting the same from the concave portion- or convex portion-formed surface of the substrate are taken down on the concave portions or the convex portions, thereby striding the concave portions with CNT or following CNT along the concave and convex as described in, for example, JP-A-2006-228818 (see for example, FIG. 16 and FIG. 21). JP-A-2006-228818 contains the description suggesting the application to an electronic device comprising plural CNTs oriented in one direction and having orientation axes continuously changed, particularly a switch (for example, claim 4). However, in the device described in JP-A-2006-228818, concave portions or convex portions must be formed on a substrate in order to separate CNT from the substrate, and a substrate having high heat resistance is required to directly grow CNT. Additionally, JP-A-2006-228818 does not recognize the technical concept of forming plural CNTs into an aggregate, and does not suggest the application to a site requiring snapping restoration property, such as a cantilever supporting movable terminals.

The applicant of the present application already proposed the technology of increasing density (0.2 to 1.5 g/cm³) of CNT aggregate oriented in a prescribed direction to thereby increase rigidity in JP-A-2007-182352, but this technology did not pay any attention to moldability to an arbitrary three-dimensional shape.

In any event, a switching element such as relay or memory, and a sensor probe generally require an elastic structure for supporting a movable contact or a tip, and it is indispensable to obtain a three-dimensional shaped structure having physical properties controlled as desired in order to form the elastic structure with CNT. However, physical properties of a structure depend on its shape. However, according to the background art as described above, an arbitrary three-dimensional shaped structure cannot integrally be formed with only CNT having anisotropy, and it is particularly difficult to obtain shape restoration property that returns to the original position when cutting off external force or electric current. The term “CNT aggregate” used in the present description means that plural CNTs (for example, number density is 5×10¹¹/cm² or more) are strongly bonded with each other by van der Waals force to form a layered state or a bundled and aggregated state.

### DISCLOSURE OF INVENTION

The invention has been made in view of the background art.

Accordingly, an object of the invention is to provide an arbitrary three-dimensional shaped structure which is formed only from CNT having controlled and stable desired physical properties and anisotropy.

Another object of the invention is to provide a method for producing the arbitrary three-dimensional shaped structure.

The background art problems are solved by the following aspects of the invention.

A first aspect of the invention provides a CNT structure constituted of CNT aggregate comprising plural CNTs oriented in the same direction, wherein the CNT has weight density of 0.1 g/cm³ or more, the structure comprises a first part contacting a base, a second part separated from the base, and a curved third part which connects the first part and the second part, and orientation axes of at least a part of CNT in the first part, the second part and the third part are continued. The term “base” used herein is not only a substrate, but may be a block-shaped base, or a prismatic or columnar structure, and also may have concave portions or convex portion (grooves, trench, steps or the like) formed thereon.

Thus, a structure is formed by high density CNT aggregate, and as a result, an arbitrary three-dimensional shaped structure having anisotropy and excellent shape-retention property and excellent restoration property can integrally be formed with only CNT. In more detail, CNT oriented in the same direction can easily be packed with the desired volume uniformly and without space, and plural CNTs are strongly bonded with each other by van der Waals force. The high density CNT aggregate is a solid substance having cohesiveness, shape retention property and shape restoration property, and is therefore a substance equipped with physical properties necessary to, for example, MEMS devices. From such a standpoint, orientation of CNT required in CNT aggregate is sufficient to an extent such that high density treatment can be carried out, and cohesiveness, shape retention property, shape restoration property and shape processability of CNT aggregate are practically allowable in putting MEMS devices into practical use, and is not always necessary to be complete.

A second aspect of the invention provides a method for producing a CNT structure constituted of CNT aggregate comprising plural CNTs oriented in the same direction, which comprises a chemical vapor phase growth step of chemically vapor phase-growing plural CNTs from a metal catalyst film formed on the surface of a substrate in the same direction to obtain CNT aggregate, an aggregate removal step of removing the CNT aggregate from the substrate, a second substrate preparation step of preparing a second substrate having a three-dimensional shaped part on the surface thereof, a three-dimensional shape forming step of forming the CNT aggregate removed from the substrate into a predetermined shape matching to the three-dimensional shaped part, a shape fixing step of fixing the predetermined three-dimensional shape by applying high density treatment to the CNT aggregate having a predetermined shape formed on the second substrate such that the weight density of the CNT is 0.1 g/cm³ or more, and an unnecessary portion removal step of selectively removing an unnecessary portion of at least the CNT aggregate fixed.

According to a third aspect of the invention, in particular, the predetermined shape preferably comprises a first part contacting the second substrate, a second part separated from the second substrate, and a curved third part which connects the first part and the second part.

According to a fourth aspect of the invention, the three-dimensional shape forming step preferably includes a liquid exposing step of exposing the CNT aggregate to a liquid and a mounting step of mounting the CNT aggregate on the second substrate, and the shape fixation step preferably includes a step of drying the CNT aggregate dipped in a liquid in a state of mounting the same on the second substrate.

According to a fifth aspect of the invention, the three-dimensional shaped part in the second substrate is a sacrifice layer, and the unnecessary portion removal step preferably includes a step of removing the sacrifice layer.

By the above constitution, CNT aggregate in a low density state just after synthesis can be formed. As a result, arbitrary three-dimensional shape can easily be obtained, and by subjecting the CNT aggregate to high density treatment after forming, high shape-retention property can be obtained. Therefore, restoring force required in, for example, movable contacts of a switch and a cantilever supporting an tip of a probe is obtained, and as a result, those can integrally be formed with only CNT. Furthermore, the conventional patterning technique and etching technique are applicable to the high density structure, making it easy to process the structure into an arbitrary shape. In particular, physical properties of the structure depend on the shape. Therefore, ability to form desired shape means that the structure having the desired physical properties can be formed. Furthermore, the substrate where CNT aggregate was synthesized and a substrate on which a CNT structure is mounted are separate substrates. Therefore, this increases the degree of freedom to design a substrate material on which a CNT structure is mounted.

The invention employs the above-described technical means or method, and therefore can exhibit great effect in providing an arbitrary three-dimensional shaped structure formed only from CNT having the desired physical properties and anisotropy, and a method for producing the same.

### BRIEF DESCRIPTION OF DRAWINGS

FIGS. 1a and 1b are schematically cross sectional views showing a basic structure of the CNT structure according to the invention.

FIG. 2 is a flow chart showing schematic steps of the production method of a CNT structure according to the invention.

FIGS. 3a to 3e are views showing a frame format of production procedures of a cantilever beam-like structure according to the invention.

FIG. 4 is a microgram image of a film-like aggregate used in the invention.

FIG. 5 is an electron microgram image showing one example of a cantilever beam-like structure according to the invention.

FIG. 6 is an electron microgram image showing an application example of a cantilever beam-like structure to a switch.

FIGS. 7a to 7e are views showing a frame format of production procedures of a relay according to the invention.

FIG. 8 is an electron microgram image showing one example of a relay produced by the procedures shown in FIGS. 7a to 7e.

FIGS. 9a and 9b are explanatory views of the actuation of the relay shown in FIG. 8.

FIG. 10 is a diagrammatic view between a gate voltage of the relay shown in FIG. 8 and source-to-drain current.

FIG. 11 is a layout view showing another example of a relay produced by the procedures shown in FIGS. 7a to 7e.

FIG. 12 is an electron microgram image of the relay shown in FIG. 11.

FIG. 13 is an electron microgram image showing one example of a simple beam-like structure according to the invention.

FIG. 14 is an electron microgram image of a substrate having relays shown in FIG. 8 integrated thereon.

FIG. 15 is a graph showing the relationship between resonant frequency and length in beam-like bodies having different length, respectively. The Table shown in FIG. 15 shows velocity of sound of CNT beam-like structure, obtained by the measurement, and velocity of sound in (111) direction of single-crystal silicon reported in the past. Furthermore, the two equations shown in FIG. 15 are theoretical equations showing the relationship between length of cantilever beam and simple beam of an elastomer, and resonant frequency.

FIG. 16 is a diagrammatic view between diameter of CNT and weight density at the time of closest packing.

### PREFERRED EMBODIMENT OF THE INVENTION

The embodiment of the invention is described in detail below by reference to the accompanying drawings.

The CNT structure of the invention comprises plural CNTs oriented in one direction, wherein the CNT has weight density of 0.1 g/cm³ or more, the structure comprises a first part contacting a base, a second part separated from the base, and a curved third part which connects the first part and the second part, and orientation axes of at least a part of CNT in the first part, the second part and the third part are continued.

### <Basic Structure>

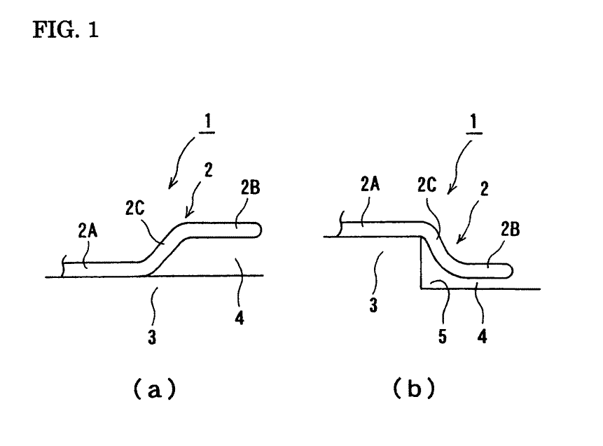

The concept of the CNT structure of the invention is shown in cross sectional views of FIG. 1a and FIG. 1b. In FIG. 1a, 1 is a CNT structure, and 2 is CNT aggregate constituting the CNT structure. The CNT structure 1 is constituted of a first part 2A contacting a base 3, a second part 2B separated from the base 3 with a space 4 (in this embodiment, the second part 2B is separated from the upper face of the base 3), and a curved third part 2C which connects the first part 2A and the second part 2B.

The plural CNTs constituting the CNT aggregate 2 have the axis lines toward a given direction, and orientation axes of CNT in the first part 2A, the second part 2B and the third part 2C are continued. In other words, the CNT aggregate 2 has high orientation (anisotropy). The orientation required in the CNT aggregate is sufficient to an extent such that high density treatment can be carried out, and that CNT aggregate 1 possesses enough unity, shape retention property, and shape processability to enable MEMS devices into practical use, and is not necessary to be complete.

In the CNTs aggregate 2, the adjacent CNTs are oriented, and are therefore strongly bonded by van der Waals force. The CNT has weight density of 0.1 g/cm³ or more as described before. Thus, when the weight density of CNT in the CNT aggregate 2 is 0.1 g/cm³ or more, CNT are uniformly packed without large gaps in between, and the CNT aggregate 2 is rigid as like a solid. As a result, mechanical properties (rigidity, flexural modulus and the like) and electrical properties (conductivity and the like) required in the CNT structure 1 to apply the same to MEMS devices and electronic devices are obtained. On the other hand, when the weight density of CNT is less than 0.1 g/cm³, large gaps are formed between CNTs constituting the CNT aggregate 2. As a result, the CNT aggregate 2 does not possess rigidity as like a solid, and the desired mechanical strength can not obtained. Additionally, in applying the known patterning technique and etching technique, solutions such as resist penetrates into the gaps between CNTs, and it is difficult to form the CNT structure 1 having the desired shape. A high weight density of CNT in the CNT aggregate is generally preferable. However, the upper limit is about 1.5 g/cm³ from the restriction of production processes.

The CNT structure 1 of the invention can maintain an arbitrary three-dimensional shape by itself, and therefore can hold the state with a free edge or central part being separated from the base 3 without a supporting part such as concave portion or convex portion on the base 3. Furthermore, when external force is acted to the free edge or the central part, the free edge or the central part can be displaced in accordance with the direction of the external force, and when the external force disappeared, the free edge or the central part can restore to the original state. Therefore, with the mechanical properties and electrical properties, the structure can suitably be used to a substrate having a flat surface on which an integrated circuit and the like are formed, as a constituent member of MEMS devices and electronic devices, such as a switch, a relay or a probe.

The CNT constituting the CNT aggregate 2 may be a single walled CNT or a multi walled CNT, and may be a mixture thereof. What kind of CNT is used can be determined according to the uses of the CNT structure 1. For example, when high conductivity and flexibility are required, a single walled CNT can be used, and when rigidity and metallic properties are emphasized, a multi walled CNT can be used.

In FIG. 1a, the second part 2B is located upper than the first part 2A contacting the base 3 in the CNT aggregate 2, but the positional relationship of those may be inverted as shown in FIG. 1b. In the embodiment shown in FIG. 1b, the positional relationship as indicated is achieved by forming a step 5 at an appropriate place of the base 3.

### <Production Method>

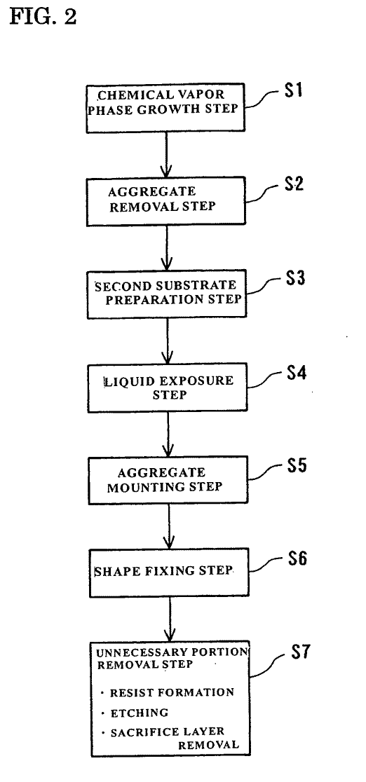

A method for producing the CNT structure according to the invention is described below by reference to FIG. 2.

The method for producing the CNT structure according to the invention comprises the following steps as shown in FIG. 2.

### A. Chemical Vapor Phase Growth Step (Step S1)

A substrate for growth (not shown) obtained by forming a metal catalyst film having pseudo 1D island patterns with a constant width on the surface thereof is used, and plural CNTs are grown from the metal catalyst film by chemical vapor deposition (hereinafter referred to as “CVD”) in a direction crossing the surface of the substrate, thereby obtaining a CNT aggregate. The growth direction of plural CNTs is generally a vertical direction to the surface of a substrate. However, the angle is not particularly restricted as long as the direction is substantially a constant direction.

B. Aggregate Removal Step (step S2)

The film-like CNT aggregate grown on the substrate for growth is removed from the substrate for growth using a jig such as a pincette.

### C. Second Substrate Preparation Step (Step S3)

A second substrate having a three-dimensional shaped part (concave part or convex part) on which a film-like CNT aggregate grown on the substrate for growth is mounted is prepared in a separate step.

### D. Three-Dimensional Shape Forming Step

D-1. The low density CNT aggregate removed from the substrate for growth is exposed to a liquid (step S4).
D-2. The low density CNT aggregate removed from the substrate for growth is mounted on a given position of a second substrate, and the CNT aggregate is located along the surface contour of the three-dimensional shaped part of the second substrate (step S5).
E. Shape Fixation Step (step S6)

The CNT aggregate exposed in a liquid is dried in the state adhered to the same to the surface of the second substrate with increased density (0.1 g/cm³ or more), and is fixed in a given shape following the surface contour of the three-dimensional shaped part of the second substrate.

### F. Unnecessary Portion Removal Step (Step S7)

Unnecessary portions are removed from the CNT layer fixed in a given shape by patterning technique and etching technique, and when the three-dimensional shaped part is formed by a sacrifice layer, the layer is also removed.

### <Cantilever Beam-Like Structure>

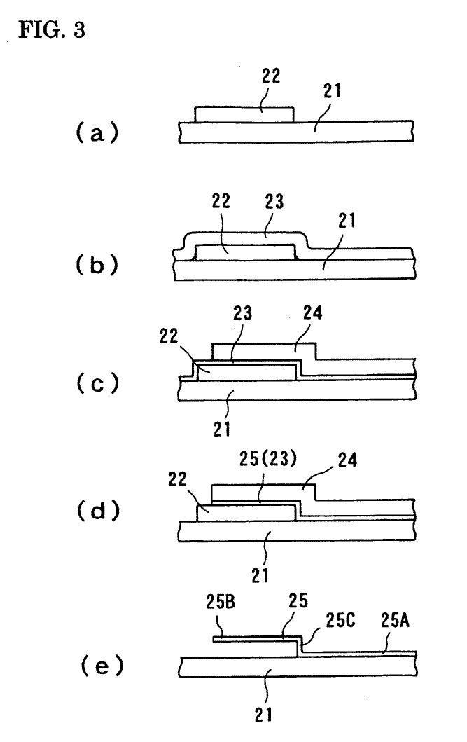

As one example of the CNT structure according to the invention, a method for producing a cantilever beam-like structure is described in more detail below by reference to FIGS. 3a to 3e.

In the chemical vapor phase growth step (step S1 in FIG. 2), a substrate for growth (not shown) having a metal catalyst film of pseudo 1D island patterns having a thickness of 1 nm and a width of 4 μm formed on the surface thereof is provided. The CNT aggregate comprising plural CNTs is grown from the metal catalyst film by the known CVD method in a constant direction crossing the surface of the substrate (for example, direction vertical to the surface of the substrate).

The substrate used can use the conventional various materials in the production technique of CNT. Typically, sheets or plates having a flat surface, comprising metals such as iron, nickel or chromium, oxides of metals, non-metals such as silicon, quartz or glass, or ceramics can be used as the substrate.

The metal catalyst film of pseudo 1D island patterns can be formed with the known film-formation techniques using appropriate use-proven metals in the production of CNT in the past. Typical examples of the metal catalyst film that can be used include metal thin films film-formed by sputtering deposition method using a resist mask, such as iron thin film, iron chloride thin film, iron-molybdenum thin film, alumina-iron thin film, alumina-cobalt thin film or alumina-iron-molybdenum thin film. Film thickness of the metal catalyst film is set to the optimum value according to the metal used as a catalyst. For example, when an iron metal is used, the film thickness is preferably from 0.1 to 100 nm.

Width of the metal catalyst film can be set according to a necessary thickness of the CNT structure finally formed, and is set to a value of 5 to 20 times the thickness of the CNT aggregate after increasing density. When the thickness of the CNT aggregate after increasing density is 10 nm or more, cohesiveness as a film can be maintained, and additionally, conductivity required in exhibiting function as an article used in electronic devices or MEMS devices is obtained. The upper limit of the thickness of the CNT aggregate after increasing density is not particularly limited. However, when used as electronic devices or MEMS devices, the thickness is preferably in a range of from about 100 nm to about 50 μm.

The carbon compound as a raw material of CNT in CVD method can use the same hydrocarbons as conventionally used. In particular, lower hydrocarbons such as methane, ethane, propane, ethylene, propylene or acetylene can be used as the preferred carbon compound.

Atmosphere gas in reaction can be any gas so long as it does not react with CNT and is inert at growth temperature. Examples of the gas that can be used include helium, argon, hydrogen, nitrogen, neon, krypton, carbon dioxide, chlorine and mixed gases of those.

Atmosphere pressure of reaction can be any pressure so long as it is within a pressure range at which CNT has been produced in the past, and can be set to an appropriate value in a range of, for example, from 102 to 10⁷ Pa.

Temperature at the growth reaction in the CVD method is appropriately determined taking into consideration reaction pressure, metal catalyst, raw material carbon source and the like. In general, when the temperature is in a range of from 400 to 1,200° C. (preferably from 600 to 1,000° C.), CNT can well be grown.

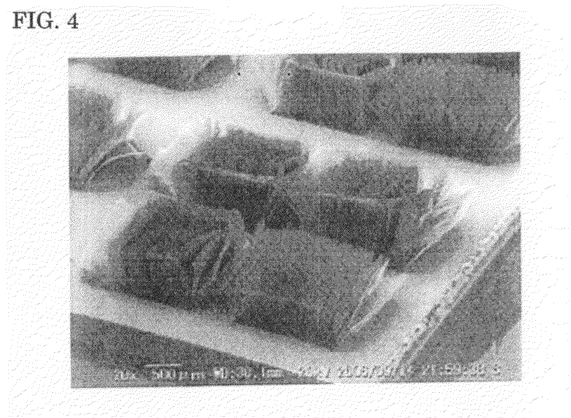

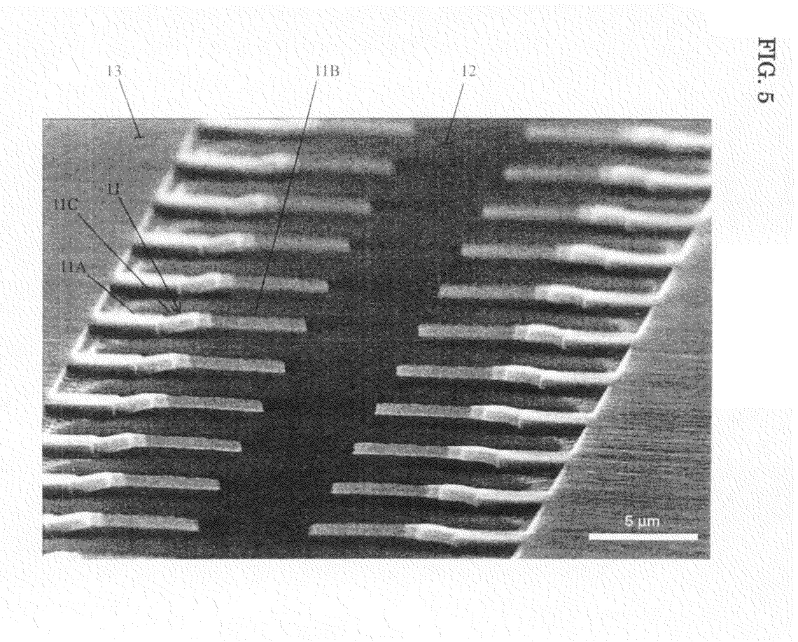

This method can obtain the CNT aggregate in which plural CNTs oriented in a constant direction have been grown in a film shape having a given size (see FIG. 4).

In producing the CNT aggregate applied to the invention, a method of growing a large amount of vertically oriented CNT in the presence of moisture and the like in reaction atmosphere as previously proposed by the same applicant as the one of the invention (see Kenji Hata et al., Water-Assisted Highly Efficient Synthesis of Impurity-Free Single-Walled Carbon Nanotubes, SCIENCE, 2004 Nov. 19, vol. 306, p. 1362-1364, or PCT/JP2008/51749) can be used.

The CNT aggregate obtained by the method has excellent properties that purity is 98% by mass or more, weight density is about 0.03 g/cm³, specific surface area is 600 to 1,300 m³ (unopen)/1,600 to 2,500 m³ (open), and ratio in size between small anisotropy and large anisotropy is 1:3 or more, with the maximum of 1:100. The CNT aggregate obtained by further subjecting to high density treatment can preferably be used in the preparation of the CNT structure of the invention.

The technique for obtaining a vertically oriented CNT aggregate applicable to the invention can appropriately use various publicly known methods. For example, a plasma CVD method (Guofang Zhong et al, Growth Kinetics of 0.5 cm Vertically Aligned Single-Walled Carbon Nanotubes, Journal of Physical Chemistry B, 2007, vol. 111, p. 1907-1910) may be used.

In the aggregate removal step (step S2 in FIG. 2), the film-like CNT aggregate produced in the chemical vapor phase growth step S1 is removed from the substrate for growth.

In the second substrate preparation step (step S3 in FIG. 2), the second substrate having a sacrifice layer as a three-dimensional shaped part is prepared. In the preparation step of the sacrifice layer, for example, a silicon substrate 21 having an Si₃N₄ layer with a thickness of 200 nm is provided. The surface of the silicon substrate is subjected to ultrasonic cleaning with isopropyl alcohol (hereinafter referred to as “IPA”), cleaned by irradiating with O₂ plasma at 300 W for one minute, and then baked at 150° C. for 10 minutes to dehydrate. For example, HSQ (hydrogen silsesquioxane) (FOX16, manufactured by Dow Corning Corporation) is applied to the treated surface of the silicon substrate by a spin coat method, and baked at 250° C. for 2 minutes. Rectangular patterns are drawn on the coated surface with an electron beam drawing apparatus (CABL8000, manufactured by CRESTEC), followed by development. Thus, a sacrifice layer 22 having a thickness of 440 nm, a width of 1 μm and a length of 5 μm is formed on the second substrate as shown in FIG. 3A.

The second substrate preparation step S3 may be conducted before the chemical vapor phase growth step S1, and the steps S1 and S3 may be conducted in parallel.

The three-dimensional shape forming step is divided into the liquid exposure step S4 and the aggregate mounting step S5. In the liquid exposure step S4, the CNT aggregate 23 removed from the substrate of growth is exposed to a liquid. In the aggregate mounting step S5, the CNT aggregate 23 removed from the substrate of growth in the aggregate removal step S2 is mounted on the silicon substrate 21 having the sacrifice layer 22 formed thereon, as the second substrate.

The liquid exposure step S4 and the aggregate mounting step S5 obtain the same result even though either of those steps is first conducted. After mounting the CNT aggregate 23 on the silicon substrate 21, a liquid can be penetrated in the CNT aggregate 23 by a spray or the like, and the CNT aggregate 23 dipped in a liquid can be taken out of the liquid and then mounted on the silicon substrate 21. Preferably, because positioning of the CNT aggregate 23 on the silicon substrate 21 is easy, the film-like CNT aggregate 23 removed in the aggregate removal step S2 is mounted and positioned so as to dip the same in the liquid present on the silicon substrate 21 while the liquid is maintaining water droplet state under surface tension. Thus, when the CNT aggregate 23 is mounted in the state that an appropriate amount of the liquid has been dropped on a site on the sacrifice layer 22 on the silicon substrate 21, the liquid penetrates into the CNT aggregate 23. As a result, the liquid exposure step S4 and the aggregate mounting step S5 can concurrently be conducted.

The liquid used in the liquid exposure step S4 is preferably a liquid having affinity with CNT and free of a residual component after CNT is dried from the wet state. Examples of the liquid that can be used include water, alcohols (IPA, ethanol, methanol or the like), acetones (acetone), hexane, toluene, cyclohexane and dimethylformamide (DMF). The dipping time in the liquid is enough so that air bubbles do not remain in the inside of the CNT aggregate 25 and the whole CNT aggregate is evenly wetted.

The CNT aggregate 23 just after the synthesis has low density (weight density: about 0.03 g/cm³) and soft, and bonding force between the adjacent CNTs is not so strong. Therefore, the surfaces of the substrate 21 and the sacrifice layer 22 are covered with the CNT aggregate 23 without space along the contour shape of those. The orientation direction of CNT in the CNT aggregate 23 on the area directly contacting the surface of the substrate 21 and the surface of the sacrifice layer 22 is a direction parallel to the surface of the substrate 21.

In the shape fixing step (step S6 in FIG. 2), typically the CNT aggregate 23 impregnated with the liquid is dried, that is, the liquid adhered to the CNT aggregate 23 is evaporated. The method for drying the CNT aggregate 23 can use natural drying at room temperature in nitrogen atmosphere, vacuum drying, heating in the presence of an inert gas such as argon, and the like.

When the CNT aggregate 23 is exposed to a liquid, CNTs are closely contacted with each other, and the entire volume of CNT is slightly contracted. The degree of close contact is further increased with evaporation of a liquid, and the volume is considerably contracted, thereby increasing density. In this case, by contact resistance to the silicon substrate 21 including the sacrifice layer 22, contraction in a direction parallel to the surfaces of the silicone substrate 21 and the sacrifice layer 22 does not substantially occur, and contraction only in a thickness direction occurs. As a result, density is increased while maintaining the orientation state and the three-dimensional shape at the time of growth. In this embodiment, the thickness of the CNT aggregate 23 formed just after removing from the substrate for growth was 4 μm, and the thickness was contracted to 500 nm after completion of the shape fixing step S6 (weight density: 0.23 g/cm³). At the same time, strong interaction acts among the high density CNT aggregate 23, the silicone substrate 21 and the sacrifice layer 22, and the CNT aggregate 23 is in a state of strongly adhering to the silicon substrate 21 and the sacrifice layer 22.

The reason that the CNT aggregate 23 contracts only in a thickness direction in the shape fixing step is presumed that surface tension is generated by penetrating the liquid between CNTs, thereby inducing contraction. Therefore, the method of increasing density in the shape fixing step is not limited to the above method so long as it is a method of generating surface tension between CNTs. For example, a method of using high temperature steam can be used.

In the unnecessary portion removal step (step S7 in FIG. 2), the surface of the CNT aggregate 23 having been increased its density and fixed in a given three-dimensional shape in the shape fixing step S6 was coated with resist HSQ (FOX16, manufactured by Dow Corning Corporation) by spin coating, and the resulting coating was baked at 250° C. for 2 minutes.

Given patterns were drawn on the resist coating film with an electron beam drawing apparatus (CABL8000, manufactured by CRESTEC), and the patterns were developed with an ammonium tetramethyl hydroxide aqueous solution (2.38%, ZTMA-100, manufactured by Nippon Zeon Co., Ltd.) to form a mask 24 (FIG. 3C). This mask was etched with a reactive ion etching apparatus (RIE-200L, manufactured by SAMCO Inc.) under the conditions of 80 W, 10 Pa and 12 min while simultaneously supplying O₂ and Ar in a flow rate of 10 sccm, and the part exposed from the mask of the CNT aggregate 23, that is, the unnecessary portion, was removed (FIG. 3D). Ar was introduced to clearly remove fluff of CNT, thereby sharp edge was obtained.

Finally, a surface layer of the mask 24 and FOX16 forming the sacrifice layer 22 were removed with buffer hydrofluoric acid (4.7% HF, 36.2% NH₄F and 59.1% H₂O, manufactured by Morita Chemical Industries Co., Ltd.) and washed with IPA, thereby obtaining a CNT aggregate 25 having a base edge part (first part) contacting the substrate 21 and a cantilever beam part (second part) 25B separated from the substrate 21, integrally connected through a curved part (third part) 25C (FIG. 3e).

Drying of a cleaning liquid is conducted by supercritical drying. In this drying, surface tension does not act on the interface between the cleaning liquid and CNT when the cleaning liquid evaporates. Therefore, even though the cantilever beam part 25B is fine, deformation does not occur, and the shape separated from the substrate 21 can generally be held.

The model of the cantilever beam-like structure actually obtained through the above each step is shown in an electron microgram image of FIG. 5. A cantilever beam-like structure 11 comprises a base edge part (first part) 11A contacting a substrate 12 and a movable piece part (second part) 11B separated from the substrate 12, integrally connected through a curved part (third part) 11C. The cantilever beam-like structure 11 is constituted of a film-like CNT aggregate 13 comprising plural CNTs oriented in a longitudinal direction of the cantilever beam-like structure 11, and can be used as a movable contact of a switch or a supporting member of an tip of a probe.

The cantilever beam-like structure 11 has rigidity that can hold a rigid three-dimensional shape by itself and has appropriate flexural modulus, and additionally has good conductivity. For example, when downward force is acted on a free edge of the movable piece part 11B, the movable piece part 11B sags downward, and returns to the original state when the force is released. In this embodiment, the movable piece part 11B of the cantilever beam-like structure 11 is formed in a tapered shape for the application to a switch, a relay, a sensor and the like. The movable piece part 11B separated from the substrate 12 has a size of a length of 4 μm, a width of 200 nm and a length of 500 nm. The size can appropriately be set according to the uses. The cross sectional shape can be various shapes such as a rectangle shape, a square shape, a circular form, an ellipse shape or a polygonal shape. The cross sectional shape and the size can be changed over a length direction.

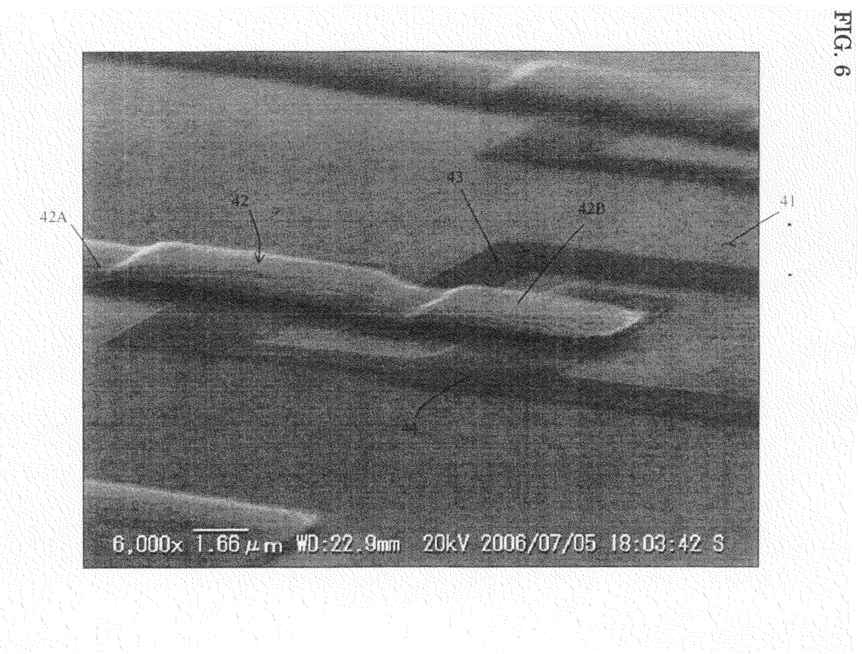

When the cantilever beam-like structure is used as a switch, a switch is obtained by the following procedures as shown in FIG. 6. A source electrode (not shown) is previously formed on a site corresponding to the base edge part 42A of the cantilever beam-like structure 42 in the substrate 41 by sputtering or the like. At the time same, a drain electrode 43 and a gate electrode 43 are previously formed on a site corresponding to a movable piece part 43B of the cantilever beam-like structure 42B in the substrate 41 by sputtering or the like and additionally, a sacrifice layer (not shown) is formed. A film-like CNT aggregates are adhered on the upper surface of those, followed by increasing density of the CNT aggregates. Unnecessary portion of the CNT aggregate is removed by patterning or etching, thereby a switch can be obtained. According to this embodiment, when voltage is applied to the gate electrode 44, the movable piece part 42B is attracted to the gate electrode 44 by electrostatic attractive force generated at that time, and as a result, the movable piece part 42B contacts the drain electrode 43, resulting in electrical conduction between the drain electrode 43 and a source electrode not shown through the cantilever beam-like structure 42. When application of voltage to the gate electrode 44 is stopped, the movable piece part 42B is returned to the original position and separated from the drain electrode 43.

### <Relay>

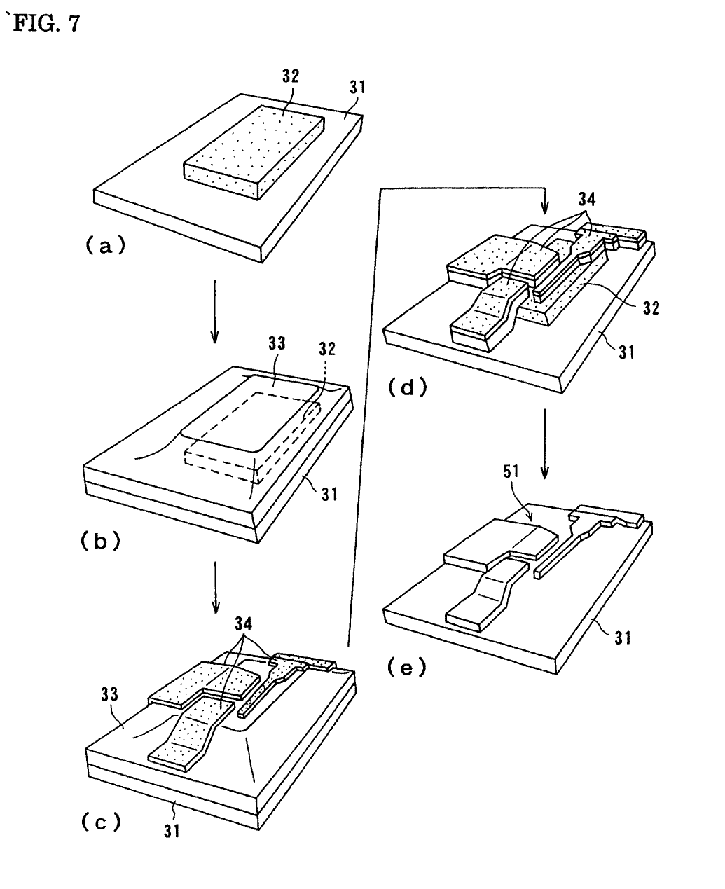

An example of applying the CNT structure of the invention to a relay is described below by reference to FIGS. 7a to 7e.

Similarly to the embodiment of the above-described cantilever beam-like structure 11, a product obtained by forming Ti and Au electrodes by sputtering on a silicon substrate 31 having Si₃N₄ layer having a thickness of 200 nm was provided. HSQ (FOX16, manufactured by Dow Corning Corporation) was applied to the product obtained above by spin coat method. The resulting coating was baked at 250° C. for 2 minutes, followed by patterning, thereby forming a sacrifice layer 32 having a thickness of 440 nm, a width of 3 μm and a length of 6 μm (FIG. 7a).

A film-like CNT aggregate 33 (thickness: 4 μm, weight density: 0.03 g/cm³) was mounted on the upper surface of the sacrifice layer, exposed to a liquid and then dried. As a result, the CNT aggregate 33 was fixed in a three-dimensional shape such that a portion covering the sacrifice layer 32 is risen, and density was increased (thickness: 500 nm, weight density: 0.23 g/cm³) (FIG. 7b).

Resist HSQ (FOX16, manufactured by Dow Corning Corporation) was applied to the surface of the CNT aggregate 33 adhered to the substrate 31 by spin coat method, and the resulting coating was baked at 250° C. for 2 minutes. Given patterns were drawn on the resist coating film with an electron beam drawing apparatus (CABL8000, manufactured by CRESTEC), and the patterns were developed with an ammonium tetramethyl hydroxide aqueous solution (2.38%, ZTMA-100, manufactured by Nippon Zeon Co., Ltd.) to form a mask 34 (FIG. 7c).

This mask was etched with a reactive ion etching apparatus (RIE-200L, manufactured by SAMCO Inc.) under the conditions of 80 W, 10 Pa and 12 min while simultaneously supplying O₂ and Ar in a flow rate of 10 sccm, and the part exposed from the mask 34 of the CNT aggregate, that is, the unnecessary portion, was removed (FIG. 7d). Ar was introduced to clearly remove fluff of CNT, thereby sharp edge was obtained.

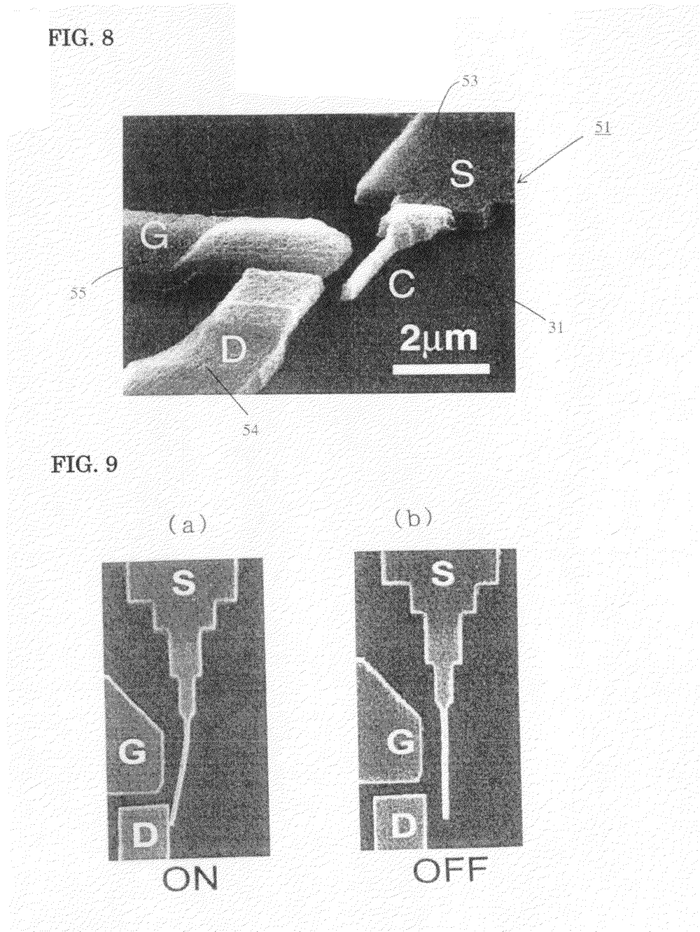

Finally, FOX16 was removed with buffer hydrofluoric acid (4.7% HF, 36.2% NH₄F and 59.1% H₂O, manufactured by Morita Chemical Industries Co., Ltd.) and cleaned with IPA, thereby obtaining a completed product of a relay 51 (FIG. 7e). Electron microgram image of the relay 51 is shown in FIG. 8.

The relay 51 comprises the substrate 31 having provided thereon a source (S) 53, a drain (D) 54 and a gate (G) 55. The source 53, the drain 54 and the gate 54 each consist of a high density CNT aggregate, and plural CNTs constituting those are all oriented in the same direction. The basic structure is a type as shown in FIG. 1a, that is, comprises a first part contacting a substrate, a second part separated from the substrate, and a curved part which connects the first part and the second part. Particularly, in the part of the source 53, orientation axes of CNT in the first part, and the second part and the third part are continued in its longitudinal direction. Furthermore, the source 53, the drain 54 and the gate 55 each are connected to the substrate 31 through a metal electrode previously formed by sputtering or the like. The part separated from the substrate 53 in the source 53 has a size of a length of 3.6 μm, a width of 170 nm and a thickness of 500 nm.

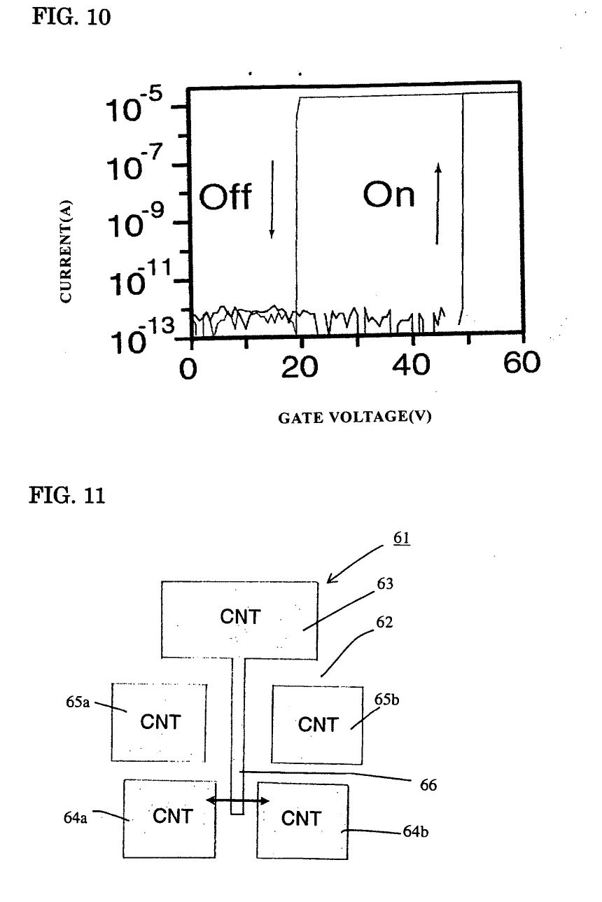

In the relay 51, when voltage applied to the gate 55 was increased (0-60V) in the state of applying voltage (5V) to the source 53 and the drain 54, the part separated from the substrate 31 in the source 53 was pulled to the drain 54 by electrostatic attractive force when applied voltage to the gate 55 reached about 50V, and these were contacted with each other, thereby conduction state was formed between the source 53 and the drain 54 (FIG. 9a). When the applied voltage to the gate 55 was decreased, the part separated from the substrate 31 in the source 53 was separated from the drain 54 and returned to the original state when the applied voltage to the gate 55 was lower than about 20V (FIG. 9b). The relationship between the applied voltage to the gate 55 and current between the source 53 and the drain 54 at that time is shown in FIG. 10. Thus, the high density CNT aggregate constituting the relay 51 has both rigidity capable of self-holding a predetermined shape and elasticity capable of deforming according to load and returning to the original shape, and additionally has good conductivity. Therefore, current off-and-on action can repeatedly be conducted.

In this embodiment, hysteresis is recognized in contact-and-separation action between the source 53 and the drain 54. This is due to the relationship between the adsorption force between the source 53 and the drain 54, and snapping restoration force of the source 53, and size of the hysteresis can appropriately be controlled by an area of a contact face between the source 53 and the drain 54, and cross section area of the free edge of the source 53.

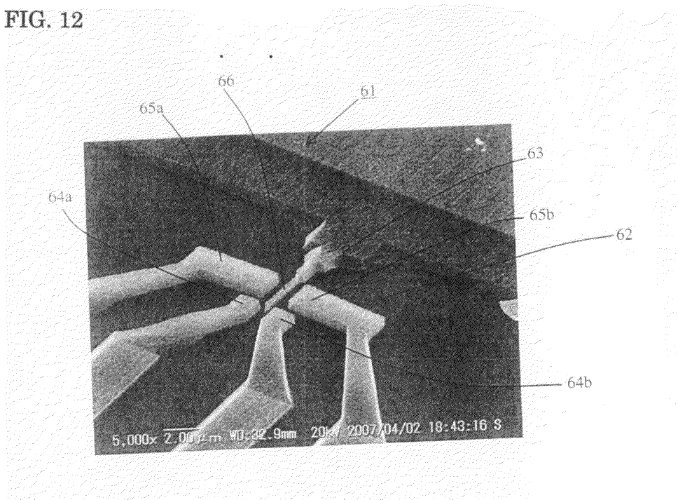

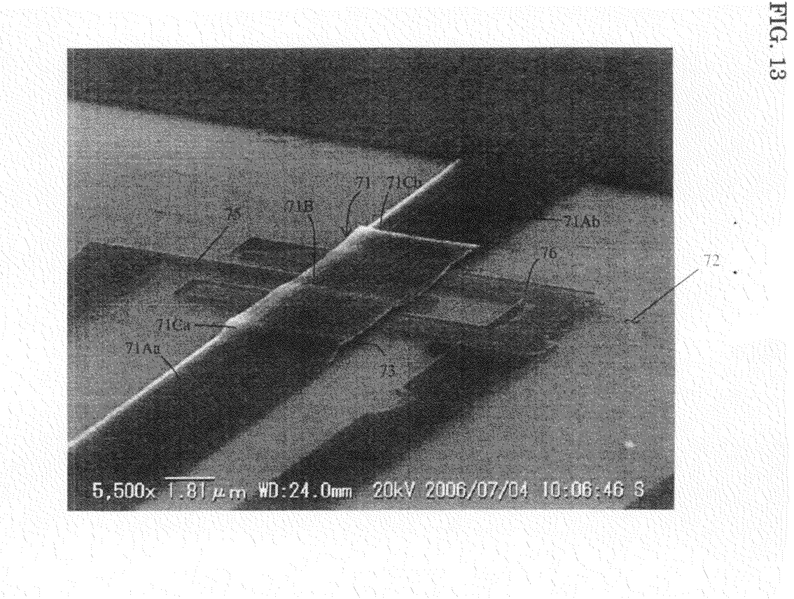

FIG. 8 exemplifies a relay of three terminals, but according to the invention, a relay of five terminals as shown in FIG. 11 and FIG. 12 can similarly be produced. A relay 61 of five terminals has the basic structure of a type shown in FIG. 1A, and is constituted so that a source 63, a first drain 64a, a second drain 64b, a first gate 65a and a second gate 65b are provided on a substrate 62, and a movable piece part 66 integrated with the source 63 is extended and exposed between (the first drain 64a and the first gate 65a) and (the second 64b and the second gate 65b). The source 63, the first and second drains 64a and 64b, the first and second gates 65a and 65b, and the movable piece part 66 each consist of high density CNT aggregate similar to the relay of three terminals described above, and plural CNTs constituting each aggregate are all oriented in the same direction.

Even in this embodiment, when voltage applied to one of the first gate 65a and the second gate 65b is increased, the source 63 is pulled to one of the first drain 64a and the second drain 64b to contact side surfaces thereof. When voltage is decreased, the source returns to the original shape, similarly to the relay of three terminals described above.

In the structure of this embodiment, adsorption powder between the first and second drains 64a and 64b and the source 63 is made to be larger than the snapping restoration force of the source 63 so that contact state between one of the first and second gates 64a and 64b, and the source 63 is maintained even though applied voltage to each of the first and second gates 65a and 65b is decreased. As a result, when voltage is temporarily applied to one of the first gate 65a and the second gate 65b, the structure can be used as a memory element in the state that the source 63 selectively contacts one of the first and second drains 64a and 64b. In this case, when voltage is applied to the gate opposite to the drain to which the source 63 contacts, the source 63 can be separated from the drain.

### <Simple Beam-Like Structure>

The CNT structure according to the invention is not limited to the above-described cantilever beam-like structure, and can be applied to a simple beam-like structure in which both ends thereof are bonded to a substrate and an intermediate part is separated from the substrate. In this case, the intermediate part separated from the substrate is formed by a sacrifice layer, similarly to the above-described production method. A model of the simple beam-like structure thus obtained is shown in an electron microgram image of FIG. 13. This simple beam-like structure 71 is constituted of high density aggregate consisting of CNT, and comprises a pair of fixing parts (first part) 71Aa and 71Ab contacting a substrate 72, a movable part (second part) 71B separated from the substrate 72 with a space 73, and a pair of curved parts (third part) 71Ca and 71Cb which connect the movable part 71B and a pair of the fixing parts 71Aa and 71Ab. The model of this simple beam-like structure 71 is such an embodiment that a pair of the fixing parts 71Aa and 71Ab and a pair of the curved parts 71Ca and 71Cb are continued trough the common movable part 71B. That is, the structure is constituted such that the first part contacting the substrate, the second part separated from the substrate, and the curved part which connects the first part and the second part are continued in two groups. The movable part 71B is generally separated from the substrate 72, and can be displaced so as to approach the substrate 72 when external force is applied.

Plural CNTs constituting the simple beam-like structure 71 are oriented in the same direction regarding the longitudinal direction of simple beam, its weight density is 0.23 g/cm³, and its size is a thickness of 500 nm and a width of 5 μm.

When the simple beam-like structure 71 is used as a switch, the switch is obtained by the following procedures. A source electrode (not shown) is previously formed on a site corresponding to the fixing parts 71Aa and 71Ab of the simple beam-like structure 71 in the substrate 72 by sputtering or the like. At the time same, a drain electrode 75 and a gate electrode 76 are previously formed on a site corresponding to a movable part 71B of the simple beam-like structure 71 in the substrate 72 by sputtering or the like and additionally, a sacrifice layer is formed. A film-like CNT aggregate is adhered on the upper surface of those, and then subjected to high density treatment. Unnecessary portion of the CNT aggregate is removed by patterning and etching, thereby a switching can be obtained. According to this embodiment, when voltage is applied to the gate electrode 76, the movable part 71B is attracted to the gate electrode 76 by electrostatic attractive force generated at that time, and as a result, the movable part 71B contacts the drain electrode 75, resulting in electrical conduction between the drain electrode 75 and a source electrode not shown through the simple beam-like structure 71. When application of voltage to the gate electrode 76 is stopped, the movable part 71B is returned to the original position and separated from the drain electrode 75.

### <Integrated Device>

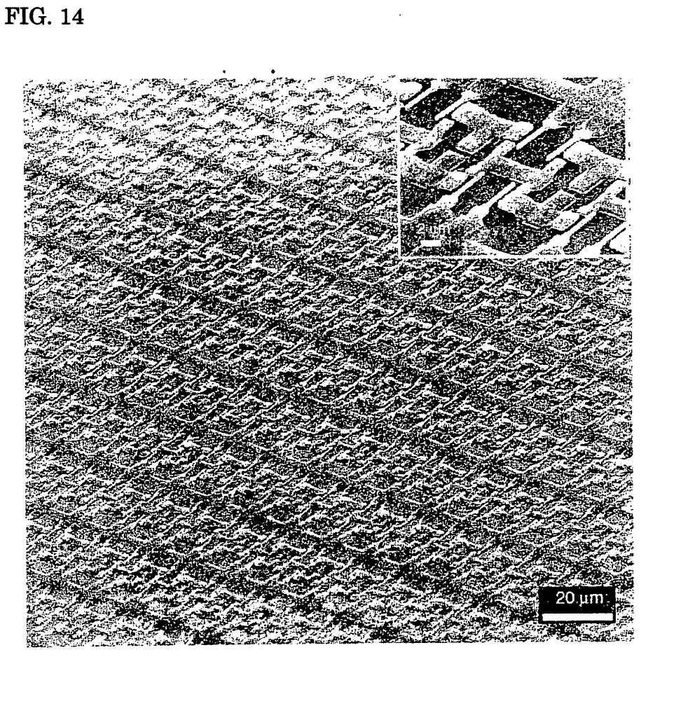

According to the invention, an integrated device to which CNT structure consisting of CNT has been applied can be produced. An example of integrating three terminal-type relay described above is shown in FIG. 14. FIG. 14 is an electron microgram image showing the state that 1,276 three terminal type relays having a size of 6.8 μm×10 μm have simultaneously been formed on one substrate within an area of 410 μm×310 μm.

### Validation Example 1

The fact that physical properties of the structure according to the invention can be controlled by a shape is described below by reference to a single beam having been subjected to high density treatment.

### Cantilever Beam Specification

Thickness: 250 nm

Weight density: 0.464 g/cm³

Length: 10, 20, 30 and 70 μm

Width: 10 μm

### Simple Beam Specification

Thickness: 310 nm

Weight density: 0.374 g/cm³

Length: 30 and 40 μm

Width: 10 μm

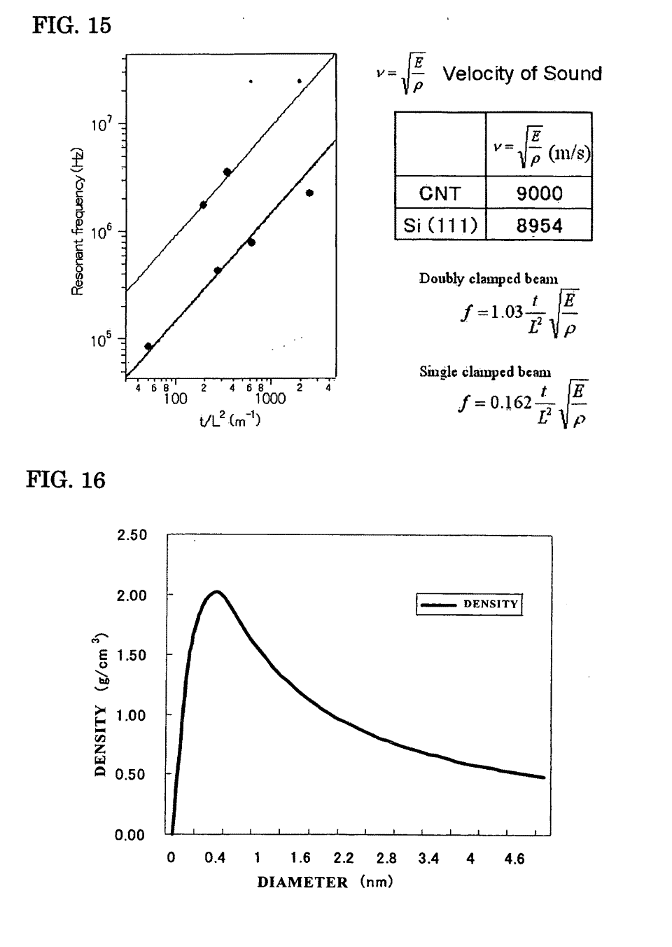

On those plural beams having different length, resonant frequency was measured by vibration detection method by heat vibration and laser reflection of a beam-like body with pulse laser (see B. Ilic, S. Krylov, K. Aubin, R. Reichenbach and H. G. Graighead, “Optical excitation of nanoelectromechanical oscillator”, Appl. Phys. Lett. 86, 193114 (2005)). As a result, it was clarified as shown in FIG. 15 that the CNT structure according to the invention shows the tendency that resonant frequency is increased as length size is decreased. The relationship between length of the structure and resonant frequency well consists with curves (thin line: simple beam, thick line: cantilever beam) of the theoretical value of elastomer drawn in FIG. 15 in both a cantilever beam and a simple beam. The curve of the theoretical value is derived from the theoretical equation (f: resonant frequency, t: thickness, L: length, E: Young's modulus, and p: density) appended at the right down part of FIG. 15 using E and ρ as fitting coefficients.

The result indicates that resonant frequency, that is, dynamic properties, of the CNT structure according to the invention depends on a shape, that is to say, can be controlled by a shape. The result further indicates that the CNT structure according to the invention can periodically be vibrated. This fact indicates that the CNT structure according to the invention functions as an elastomer, that is, has shape-retention properties and shape restoration properties.

The table appended at right upper part of FIG. 15 shows velocity of sound which is one of barometers showing dynamic properties of a substance. A substance having high velocity of sound is lightweight and rigid, and is therefore said to be a material suitable for mechanical element of MEMS device and the like. From the measurement result, the velocity of sound of the CNT structure according to the invention obtained by the fitting coefficients is an equivalent value or more as compared with properties in crystal orientation (111) direction which is the maximum value of single crystal silicon (Si) reported, and this indicates that the CNT structure according to the invention is extremely suitable for MEMS devices and the like.

The film-like CNT aggregate before high density treatment has extremely small weight, and measurement of its weight density is difficult. Therefore, the weight density was estimated from density of a bulk-like CNT aggregate grown from a substrate having a metal catalyst film formed on the entire surface thereof without applying pseudo 1D island patterning thereto.

Density of the bulk-like CNT aggregate is calculated by weight/volume, but it is known that density of the bulk-like CNT aggregate becomes constant under various conditions. For example, the literature reference (Don N. Futaba, et al, 84% Catalyst Activity of Water-Assisted Growth of Single Walled Carbon Nanotube Forest Characterization by a Statistical and Macroscopic Approach, Journal of Physical Chemistry B, 2006, vol. 110, p. 8035-8038) reports that weight density of a bulk-like CNT aggregate is a constant value (0.029 g/cm³) when height of the aggregate is from 200 μm to 1 mm. In other words, it can be inferred that density of a film-like CNT aggregate grown using growth conditions and catalyst substantially equal to the growth of the bulk-like CNT aggregate does not greatly differ from the density of the bulk-like CNT aggregate.

When compressibility of the film-like CNT aggregate in high density step is defined (compressibility=original thickness/thickness after high density treatment), weight density of the film-like CNT aggregate after high density treatment is (CNT density=compressibility×0.029 g/cm³). When weight density after high density treatment of a film-like CNT aggregate in each thickness is derived by this, adhesion to a substrate is sufficiently maintained even in the film-like CNT aggregate having weight density of 0.11 g/cm³, and patterning similar to each Example described above was possible. On the other hand, in the case of the film-like CNT aggregate before high density treatment (weight density: 0.029 g/cm³), adaptation of the publicly known etching and lithography technologies were substantially impossible due to lack of adhesion to a substrate and corrosion of a resist. In view of the above, the range of weight density after high density treatment in the CNT structure adaptable to the invention was defined as 0.1 g/cm³.

Weight density of the film-like CNT aggregate controllable in the invention can theoretically be achieved in a wide range by controlling a diameter of CNT. Assuming that all the CNTs have equivalent diameters and all the CNTs are closest-packed by the high density step, it can easily be calculated that CNT density after high density treatment is increased as a diameter of CNT is decreased (see FIG. 16). The average diameter of CNT of the film-like CNT aggregate used in the Examples is about 2.8 nm. Weight density assuming that CNT are closest-packed in this case is about 0.78 g/cm³ as shown in FIG. 16. In this regard, it is understood that the diameter of CNT can be minimized (about 1.0 nm) by using the technology reported in the literature reference (Ya-Qiong Xu, et al, Vertical Array Growth of Small Diameter Single-Walled Carbon Nanotubes, J. Am. Chem. Soc., 128 (20), 6560-6561, 2006). It is considered from this fact that weight density can be increased to a maximum of about 1.5 g/cm³ by decreasing the diameter of CNT.

1. A carbon nanotube structure constituted of a carbon nanotube aggregate comprising plural carbon nanotubes oriented in the same direction,
wherein the carbon nanotube has weight density of 0.1 g/cm³ or more,
the structure comprises a first part contacting a base, a second part separated from the base, and a curved third part which connects the first part and the second part, and
orientation axes of at least a part of carbon nanotubes in the first part, the second part and the third part are continued.

2. A method for producing a carbon nanotube structure constituted of carbon nanotube aggregate comprising plural carbon nanotubes oriented in the same direction, which comprises:
a chemical vapor phase growth step of chemically vapor phase-growing plural carbon nanotubes from a metal catalyst film formed on the surface of a substrate in the same direction to obtain carbon nanotube aggregate,
an aggregate removal step of removing the carbon nanotube aggregate from the substrate,
a second substrate preparation step of preparing a second substrate having a three-dimensional shaped part on the surface thereof,
a three-dimensional shape forming step of forming the carbon nanotube aggregate removed from the substrate into a predetermined shape matching to the three-dimensional shaped part,
a shape fixing step of fixing the predetermined shape by applying high density treatment to the carbon nanotube aggregate having a predetermined shape formed on the second substrate such that the weight density of the carbon nanotube is 0.1 g/cm³ or more, and
an unnecessary portion removal step of selectively removing an unnecessary portion of at least the carbon nanotube aggregate fixed.

3. The method for producing a carbon nanotube structure as claimed in claim 2, wherein the predetermined shape comprises a first part contacting the second substrate, a second part separated from the second substrate, and a curved third part which connects the first part and the second part.

4. The method for producing a carbon nanotube structure as claimed in claim 2, wherein the three-dimensional shape forming step includes a liquid exposing step of exposing the CNT aggregate to a liquid and a mounting step of mounting the CNT aggregate on the second substrate, and the shape fixing step includes a step of drying the carbon nanotube aggregate dipped in a liquid in a state of mounting the same on the second substrate.

5. The method for producing a carbon nanotube structure as claimed in claim 2, wherein the three-dimensional shaped part in the second substrate is a sacrifice layer, and the unnecessary portion removal step includes a step of removing the sacrifice layer.

6. The method for producing a carbon nanotube structure as claimed in claim 3, wherein the three-dimensional shape forming step includes a liquid exposing step of exposing the CNT aggregate to a liquid and a mounting step of mounting the CNT aggregate on the second substrate, and the shape fixing step includes a step of drying the carbon nanotube aggregate dipped in a liquid in a state of mounting the same on the second substrate.

7. The method for producing a carbon nanotube structure as claimed in claim 3, wherein the three-dimensional shaped part in the second substrate is a sacrifice layer, and the unnecessary portion removal step includes a step of removing the sacrifice layer.

8. The method for producing a carbon nanotube structure as claimed in claim 4, wherein the three-dimensional shaped part in the second substrate is a sacrifice layer, and the unnecessary portion removal step includes a step of removing the sacrifice layer.

9. The method for producing a carbon nanotube structure as claimed in claim 6, wherein the three-dimensional shaped part in the second substrate is a sacrifice layer, and the unnecessary portion removal step includes a step of removing the sacrifice layer.
